(19) United States
(12) Patent Application Publication
(10) Pub. No.: US 2024/0421250 A1
(43) Pub. Date: Dec. 19, 2024

(54) SEMICONDUCTOR STRUCTURE

(71) Applicant: EPISTAR CORPORATION, Hsinchu (TW)

(72) Inventors: Yu-Hsiang YEH, Hsinchu (TW); Shih-Wei WANG, Hsinchu (TW)

(21) Appl. No.: 18/737,766

(22) Filed: Jun. 7, 2024

(30) Foreign Application Priority Data
Jun. 13, 2023 (TW) 112122032

(51) Int. Cl. H01L 33/12; H01L 33/00; H01L 33/32

(52) U.S. Cl. CPC H01L 33/12; H01L 33/007; H01L 33/32

(57) ABSTRACT

A semiconductor structure includes a first semiconductor structure having a first conductivity type, a second semiconductor structure having a second conductivity type, an active structure disposed between the first semiconductor structure and the second semiconductor structure, a stress release structure disposed between the first semiconductor structure and the active structure, and an indium-containing layer disposed between the stress release structure and the first semiconductor structure. An indium content of the indium-containing layer is greater than an indium content of the stress release structure.

### CROSS-REFERENCE TO RELATED APPLICATIONS

This disclosure claims the right of priority of TW Application No. 112122032 filed on Jun. 13, 2023, and the content of which is hereby incorporated by reference in its entirety,

### BACKGROUND

### Technical Field

The present disclosure relates to a semiconductor structure, in particular, a semiconductor structure of a light-emitting diode.

### Description of the Related Art

The light-emitting diode (LED) is a sort of solid-state semiconductor element, which has the advantages of low power consumption, low heat generation, long lifetime, shockproof, small size, high response speed, and good optical-electrical characteristics like stable emission wavelength. Therefore, light-emitting diodes have been widely applied to household appliances, equipment indicator lights, optoelectronic products, and so forth. An LED chip includes an epitaxial stack grown on a substrate, and the emission wavelength and brightness of the chip can be determined by the epitaxial stack.

### SUMMARY

A semiconductor structure of embodiments of the present disclosure is provided. The semiconductor structure can avoid surface defects forming in the active structure to reduce non-radiative recombination centers (NRCs), thereby improving light-emitting efficiency of a light-emitting device.

In accordance with an embodiment of the present disclosure, a semiconductor structure is provided. The semiconductor structure includes a first semiconductor structure, a second semiconductor structure, an active structure, a stress release layer and an indium-containing layer. The first semiconductor structure has a first conductivity type. The second semiconductor structure has a second conductivity type. The active structure is disposed between the first semiconductor structure and the second semiconductor structure. The stress release structure is disposed between the first semiconductor structure and the active structure. The indium-containing layer is disposed between the active structure and the first semiconductor structure. An indium content of the indium-containing layer is greater than an indium content of the stress release structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of a semiconductor structure 100 in accordance with an embodiment of the present disclosure.

FIG. 2 is a schematic cross-sectional view of a semiconductor structure 100 in accordance with another embodiment of the present disclosure.

FIG. 3 is a schematic cross-sectional view of a semiconductor structure 100 in accordance with another embodiment of the present disclosure.

FIG. 4 is a flow chart of a manufacturing method of a semiconductor structure 200A in accordance with an embodiment of the present disclosure.

FIG. 5 is a flow chart of a manufacturing method of a semiconductor structure 200B in accordance with another embodiment of the present disclosure.

FIG. 6 is a flow chart of a manufacturing method of a semiconductor structure 200C in accordance with another embodiment of the present disclosure.

FIG. 7 is a schematic cross-sectional view of a light-emitting device 300 in accordance with an embodiment of the present disclosure.

FIG. 8 is a schematic cross-sectional view of a light-emitting package 400A in accordance with an embodiment of the present disclosure.

FIG. 9 is a schematic cross-sectional view of a light-emitting package 400B in accordance with another embodiment of the present disclosure.

FIG. 10 is a schematic cross-sectional view of a light-emitting package 400C in accordance with another embodiment of the present disclosure.

FIG. 11 is a schematic cross-sectional view of a light-emitting apparatus 500A in accordance with an embodiment of the present disclosure.

FIG. 12 is a schematic cross-sectional view of a light-emitting apparatus 500B in accordance with an embodiment of the present disclosure.

### DETAILED DESCRIPTION OF THE EMBODIMENTS

The following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is understood that, the terms first, second, third, etc. used herein to describe various elements, components, regions, layers and/or sections are not used to limit them. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”.

The terms, such as “coupled to” and “electrically connected to”, disclosed herein encompass all means of directly and indirectly electrical connection. For example, when a first element is referred to as being “coupled to” or “electrically connected to” a second element, it may be directly coupled or electrically connected to the second element, or intervening elements may be presented.

Although the disclosure is described with respect to specific embodiments, the principles of the invention, as defined by the claims appended herein, can obviously be applied beyond the specifically described embodiments of the invention described herein. Moreover, in the description of the present disclosure, certain details have been omitted in order to not obscure the inventive aspects of the disclosure. The omitted details are within the knowledge of a person of ordinary skill in the art.

The present disclosure relates to stack configurations and material compositions of a semiconductor structure. The semiconductor structure may be a semiconductor light-emitting stack applied to a light-emitting device, such as a light-emitting diode or a laser diode. The semiconductor material constituting the semiconductor light-emitting device includes group III-V material, but is not limited thereto. In accordance with embodiments of the present disclosure, in the semiconductor structure, the indium-containing layer is provided between the first semiconductor structure with a first conductivity type and the active structure, and the indium content of the indium-containing layer is greater than that of any semiconductor layer between the first semiconductor structure and the active structure, except for the active structure. Indium atoms in the indium-containing layer can combine with surface defects in the semiconductor structure resulted from high-temperature semiconductor growth, and the surface defects can be confined in the indium-containing layer to reduce or avoid surface defects forming in active structures. Accordingly, non-radiative recombination centers (NRCs) are reduced and the light-emitting efficiency of the light-emitting device is improved.

FIG. 1 is a schematic cross-sectional view of a semiconductor structure 100 in accordance with an embodiment of the present disclosure. The semiconductor structure 100 includes multiple group III-V semiconductor layers stacked in sequence, such as AlInGaN series material AlₓIn_{y}Ga_{(1-x-y)}N or AlInGaP series material AlₓIn_{y}Ga_{(1-x-y)}P, where 0≤x, y≤1; (x+y)≤1. When the material of the active structure 130 includes AlInGaP series material, a red light with a wavelength between 610 nm and 650 nm may be emitted from the active structure 130. When the material of the active structure 130 includes InGaN series material, a blue light with a wavelength between 400 nm and 490 nm, or green light with a wavelength between 530 nm and 570 nm may be emitted from the active structure 130. When the material of the active structure 130 includes AlGaN series material or AlInGaN series material, an ultraviolet light with a wavelength between 220 nm and 400 nm may be emitted from the active structure 130. In addition, depending on requirements, these group III-V semiconductor layers may contain dopants to form n-type or p-type group III-V semiconductor layers. Referring to FIG. 1, the semiconductor structure 100 includes a first semiconductor structure 110, a second semiconductor structure 120, and the active structure 130 disposed between the first semiconductor structure 110 and the second semiconductor structure 120. The first semiconductor structure 110 may be first conductivity type, such as n-type. The second semiconductor structure 120 may be second conductivity type, such as p-type.

In some embodiments, the first semiconductor structure 110 may be intentionally or unintentionally doped to be the first conductivity type. The first semiconductor structure 110 may include a contact layer 102 with a greater concentration of the first-conductivity-type dopant and an intermediate layer 118 with a less concentration of the first-conductivity-type dopant stacked on the contact layer 102. The contact layer 102 and the intermediate layer 118 of the first semiconductor structure 110 are composed of AlGaN series material such as gallium nitride (GaN) or aluminum gallium nitride (AlGaN), and the first-conductivity-type dopant (n-type) is, for example, silicon (Si). The contact layer 102 with a greater concentration of the first-conductivity-type dopant can provide a lower contact resistance for the electrode subsequently formed on the first semiconductor structure 110, while the intermediate layer 118 with a lower concentration of the first-conductivity-type dopant can improve the film quality of the semiconductor structure 100, facilitate current diffusion, or prevent the semiconductor structure 100 from being damaged by surges. The buffer structure may reduce dislocation caused by lattice mismatch between a growth substrate and the first semiconductor structure 110, thereby improving the film quality of the semiconductor structure 100, such as epitaxial quality, and reducing leakage current. The material of the buffer structure may include AlGaN series material containing the first-conductivity-type (n-type) dopant, such as aluminum nitride (AlN), nitride Gallium (GaN) or aluminum gallium nitride (AlGaN).

In addition, the semiconductor structure 100 further includes a stress release structure 117 disposed between the first semiconductor structure 110 and the active structure 130. In addition, in order to gradually transit the composition and doping of the first semiconductor structure 110 to those of the active structure 130, the first semiconductor structure 110 may further include a transition layer 115 disposed between the contact layer 102 and the stress release structure 117, or between the intermediate layer 118 and the stress release structure 117. In some embodiments, the transition layer 115 includes a first group III-V semiconductor sub-layer 111 and a second group III-V semiconductor sub-layer 112 sequentially stacked on the contact layer 102 from bottom to top. The materials of the first group III-V semiconductor sub-layer 111 and the second group III-V semiconductor sub-layer 112 may include gallium nitride (GaN) or indium gallium nitride (InGaN). In some embodiments, the materials of the first group III-V semiconductor sub-layer 111 and the second group III-V semiconductor sub-layer 112 may include aluminum gallium nitride (AlGaN). The first group III-V semiconductor sub-layer 111 and the second group III-V semiconductor sub-layer 112 may include the same or different concentration of the first-conductivity-type dopant, such as silicon (Si). The concentration of the first-conductivity-type dopant in the second group III-V semiconductor sub-layer 112 may be greater or less than that in the first group III-V semiconductor sub-layer 111. In one embodiment, when the concentration of the first-conductivity-type dopant in the second group III-V semiconductor sub-layer 112 is greater than that in the first group III-V semiconductor sub-layer 111, the first group III-V semiconductor sub-layer 111 or a structure including the first group III-V semiconductor sub-layer 111 and the intermediate layer 118 can form a high resistance structure to laterally diffuse the current injected from the contact layer 102, or prevent the semiconductor structure 100 from being damaged by surges, thereby improving the anti-ESD capability of the semiconductor structure 100. In one embodiment, the transition layer 115 may include one of the first group III-V semiconductor sub-layer 111 and the second group III-V semiconductor sub-layer 112.

In some embodiments, the stress release structure 117 may include a first stress release layer 114 disposed on the indium-containing layer 116, and a second stress release layer 113 disposed between the first stress release layer 114 and the indium-containing layer 116 sequentially stacked on the transition layer 115 from bottom to top. Each of the first stress release layer 114 and the second stress release layer 113 may be a stacked structure formed by alternating two semiconductor sub-layers composed of different materials, such as a superlattice structure. The tensile or compressive stress resulted from the two alternated semiconductor layers may eliminate or reduces the stress accumulated from the substrate (not shown) to the transition layer 115. The stacked structures of the first stress release layer 114 and the second stress release layer 113 may include two or more stacked pairs. Each stacked pair may include two layers of different materials, such as a gallium nitride (GaN) layer and an indium gallium nitride (InGaN) layer, or an aluminum gallium nitride (AlGaN) layer and a gallium nitride (GaN) layer are stacked in pairs. The stress release structure 117 may be a semiconductor bulk composed of different material composition with the same function, such as a semiconductor bulk layer composed of graded-composition group III elements. In some embodiments, an indium content of the second stress release layer 113 is greater than that of the first stress release layer 114. In some embodiments, the first stress release layer 114 includes more pairs of alternately stacked compressive-stress sub-layers and tensile-stress sub-layers than the second stress release layer 113, but is not limited thereto.

In some embodiments, the active structure 130 may include a multiple quantum well (MQW) structure, a single heterostructure, or a double heterostructure. In addition, in some embodiments, the second semiconductor structure 120 may be an AlInGaN series material. In one embodiment, the second semiconductor structure 120 is doped with a second-conductivity-type dopant, such as magnesium (Mg), and the doping concentration is greater than 5×10¹⁸/cm³, such as greater than 1×10¹⁹/cm³. In one embodiment, the second semiconductor structure 120 may further includes the first-conductivity-type dopant, such as silicon (Si), to be in ohmic contact with the second electrode 150 of the light-emitting device 300 of FIG. 4. In some embodiments, the second semiconductor structure 120 may include a multi-layer structure, such as a superlattice structure. By adjusting the doping concentration or gradually adjusting the material composition of the multi-layer structure, the film quality, such as the epitaxial quality of the second semiconductor structure 120 can be improved. In one embodiment, an electron blocking layer (not shown) may be further disposed between the active structure 130 and the second semiconductor structure 120. The electron blocking layer can block electrons injected from the first semiconductor structure 110, through the active structure 130 and into the second semiconductor structure 120 without recombined with holes in the active structure 130. One or more layers may be disposed between the second semiconductor structure 120 and the electron blocking layer. For example, a diffusion prevention layer (not shown) may be disposed between the electron blocking layer and the active structure 130. The diffusion prevention layer can prevent the second-conductivity-type dopant of the second semiconductor structure 120 or the electron blocking layer from diffusing into the active structure 130, thereby preventing from deteriorating the epitaxial quality of the active structure 130 or reducing the efficiency of the active structure 130.

In accordance with some embodiments of the present disclosure, an indium-containing layer 116 may be disposed between the stress release structure 117 and the contact layer 102 of the first semiconductor structure 110, and the indium content of the indium-containing layer 116 is greater than that of the stress release structure 117. The indium content of the indium-containing layer 116 may be about 2 to 3 times that of the stress release structure 117. In some embodiments, the composition of the indium-containing layer 116 may be indium gallium nitride Inₓ₁Ga₁₋ₓ₁N, and 0<x1≤0.2. In other embodiments, the composition of the indium-containing layer 116 may be indium aluminum nitride Inₓ₂Al₁₋ₓ₂N, and 0<x2≤0.15. In some embodiments, a thickness of the indium-containing layer 116 may be between 0.25 nm to 20 nm, or between 3 nm and 10 nm. In specific, the thickness of the indium-containing layer 116 may be about 7 nm. In order to provide a better growth template for the active structure 130, the semiconductor stack disposed between a growth substrate and the active structure 130 may have a denser epitaxial structure compared with the active structure 130 so as to have a higher epitaxial surface reflectivity. The semiconductor stack may include the buffer structure, the first semiconductor structure 110, or the transition layer 115. The semiconductor stack can be formed at a growth temperature higher than that of the active structure 130, such as an epitaxial growth temperature between 800° C. and 1200° C. However, a surface of the semiconductor stack may be cracked due to high temperatures, thereby forming surface defects, such as nitrogen vacancies, gallium vacancies, and a complex of gallium and nitrogen vacancies or a combination thereof. These surface defects may extend to the active structure 130 during epitaxial growth, and carriers in the active structure 130 may be trapped in these surface defects instead of recombination for radiating light, that is, these surface defects form non-radiative recombination centers (NRCs), resulting in reducing the light-emitting efficiency of the active structure 130. In accordance with some embodiments of the present disclosure, indium atoms in the indium-containing layer 116 are combined with surface defects generated in any layer of the foregoing semiconductor stack, so that these surface defects can be confined within the indium-containing layer 116 instead of extending to the active structure 130, thereby preventing from forming non-radiative recombination centers (NRCs) in the active structure 130, so as to improve the internal quantum efficiency of the active structure 130, thereby improving the light-emitting efficiency of the semiconductor structure 100.

In one embodiment, as shown in FIG. 1, the indium-containing layer 116 may be disposed between the transition layer 115 and the stress release structure 117. In accordance with the foregoing embodiments, the transition layer 115 includes the first group III-V semiconductor sub-layer 111 and the second group III-V semiconductor sub-layer 112, and the stress release structure 117 includes the first stress release layer 114 and the second stress release layer 113. The indium-containing layer 116 may be disposed between the second group III-V semiconductor sub-layer 112 and the second stress release layer 113. Similarly, in other embodiments, the transition layer 115 may include a single layer. For example, when the transition layer 115 includes one of the first group III-V semiconductor sub-layer 111 and the second group III-V semiconductor sub-layer 112, the indium-containing layer 116 is disposed between the first group III-V semiconductor sub-layer 111 and the stress release structure 117, or between the second group III-V semiconductor sub-layer 112 and the stress release structure 117. In some embodiments, when the first stress release layer 114 and/or the second stress release layer 113 contains indium, the indium composition in any sub-layer of the stress release structure 117 can be increased to serve as the indium-containing layer 116, thereby having the effect of confining the surface defects. For example, the second stress release layer 113 may include the indium-containing layer 116. In the above embodiments, compared with the embodiment that the indium-containing layer 116 is in the stress release structure 117, the embodiment that the indium-containing layer 116 disposed between the transition layer 115 and the stress release structure 117 has a better effect of confining the surface defects. This is because the indium atoms in the indium-containing layer 116 can combine with the surface defects at a position of the first semiconductor structure 110 far away from the active structure 130, thereby preventing the surface defects from extending to the active structure 130. In the above embodiment, the indium-containing layer 116 and the stress release structure 117 together provide the effect of confining the surface defects to reduce non-radiative recombination centers (NRCs) in the active structure 130, thereby improving the light-emitting efficiency of the semiconductor structure 100. In some embodiments where the stress release structure 117 contains indium, the indium content of each indium-containing sub-layer, such as InGaN, that constitutes the stack of the stress release structure 117 may be different. For example, the indium-containing sub-layer farther away from the active structure 130 may have a greater indium content. The indium-containing layer 116 can be the indium-containing sub-layer farthest away from the active structure 130 in the stress release structure 117 and having a greater indium content. For example, the indium-containing layer 116 can be an indium-containing sub-layer in the second stress release layer 113.

In the embodiments where the stress release structure 117 contains indium, the indium content of the indium-containing layer 116 is greater than that of the stress release structure 117. For example, the indium content of the indium-containing layer 116 may be 2 to 3 times that of the stress release structure 117. Therefore, the indium-containing layer 116 may serve as a primary semiconductor layer for confining the surface defects. A light-emitting device made of the semiconductor structure 100 having the stress release structure 117 but without the indium-containing layer 116 is taken as a comparative example. A light-emitting device made of the semiconductor structure 100 having the stress release structure 117 and the indium-containing layer 116 is taken as an embodiment. In a photoelectric test under the same driving current, the brightness of the light-emitting device of the embodiment is 0.4% to 0.8% greater than that of the comparative example.

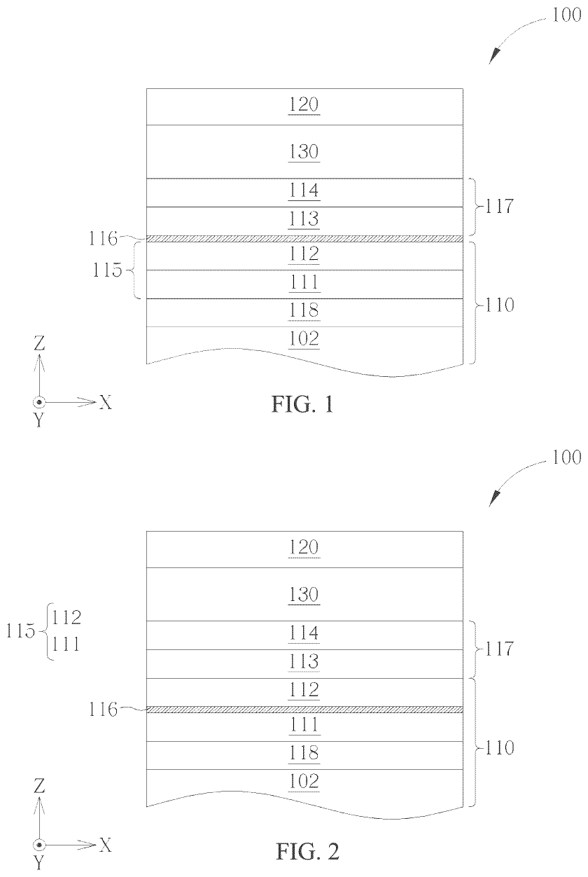

FIG. 2 is a schematic cross-sectional view of a semiconductor structure 100 in accordance with another embodiment of the present disclosure. In the embodiment, the indium-containing layer 116 may be disposed between the first group III-V semiconductor sub-layer 111 and the second group III-V semiconductor sub-layer 112 of the transition layer 115. Since the indium content of the indium-containing layer 116 is greater than that of the stress release structure 117, and the indium-containing layer 116 is disposed on the first group III-V semiconductor sub-layer 111, the indium atoms of the indium-containing layer 116 can combine with the surface defects extended to the first group III-V semiconductor sub-layer 111. Moreover, in the embodiment where the stress release structure 117 contains indium, the indium-containing layer 116 and the stress release structure 117 together can provide the effect for confining the surface defects to reduce non-radiation recombination centers (NRCs) in the active structure 130, thereby improving the light-emitting efficiency of the semiconductor structure 100. In another embodiment, similar to the embodiment of FIG. 1, the semiconductor structure 100 in FIG. 2 may further include another indium-containing layer (not shown) between the transition layer 115 and the stress release structure 117. The details of the semiconductor structure 100 already described in the description of FIG. 1 will not be repeated here.

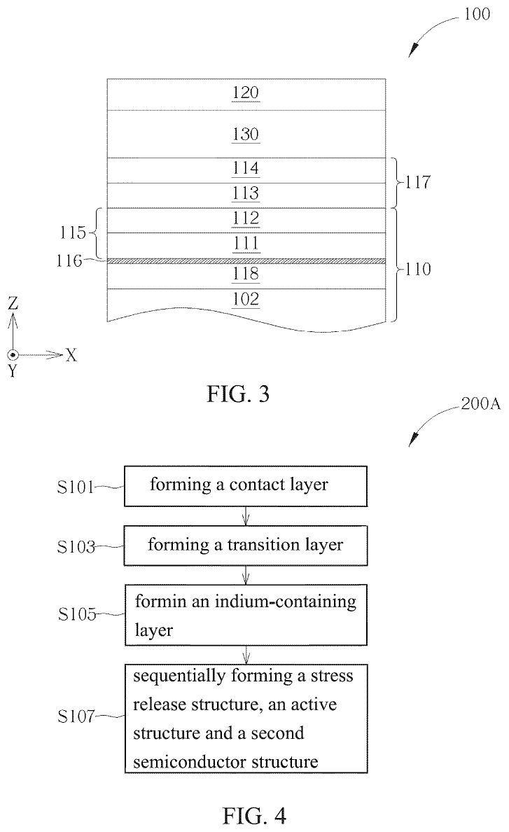

FIG. 3 is a schematic cross-sectional view of a semiconductor structure in accordance with another embodiment of the present disclosure. In the embodiment, the indium-containing layer 116 may be disposed between the contact layer 102 and the first group III-V semiconductor sub-layer 111 of the transition layer 115. When the first semiconductor structure 110 includes the intermediate layer 118, the indium-containing layer 116 may be disposed between the intermediate layer 118 and the first group III-V semiconductor sub-layer 111 of the transition layer 115. The indium atoms of the indium-containing layer 116 may firstly combine with the surface defects of the contact layer 102 or the intermediate layer 118, and in the embodiment where the stress release structure 117 contains indium, the indium-containing layer 116 and the stress release structure 117 can together provide the effect for confining the surface defects to reduce non-radiation recombination centers (NRCs) in the active structure 130, thereby improving the light-emitting efficiency of the semiconductor structure 100. The details of the semiconductor structure 100 already described in the description of FIG. 1 will not be repeated here.

In some embodiments not shown, the indium-containing layer 116 may be disposed at other locations between the contact layer 102 and the stress release structure 117, such as between the contact layer 102 and the intermediate layer 118.

FIG. 4 is a flow chart of a manufacturing method of a semiconductor structure 200A in accordance with an embodiment of the present disclosure. As shown in FIG. 1 and FIG. 4, in step S101, the contact layer 102 of the first semiconductor structure 110 is formed on a growth substrate (not shown) by epitaxial growth, and the intermediate layer 118 can be selectively grown on the contact layer 102. The growth temperature of the intermediate layer 118 may be higher than that of the contact layer 102. The growth substrate is, for example, a sapphire substrate. In one embodiment, the growth substrate has a patterned surface (not shown) where the semiconductor structure 100 is disposed on. The contact layer 102 of the first semiconductor structure 110 is composed of, for example, gallium nitride (n-GaN) containing the first-conductivity-type (n-type) dopant, such as silicon (Si). Next, in step S103, the transition layer 115 is formed on the contact layer 102 by epitaxial growth. In some embodiments, a transition layer 115 is formed on the intermediate layer 118. The growth temperature of the transition layer 115 is lower than that of the contact layer 102 or the intermediate layer 118, and the doping concentration of the first-conductivity-type dopant thereof is lower than that of the contact layer 102 to form subsequent semiconductor layers, such as the stress release structure 117 and the active structure 130. In some embodiments, the transition layer 115 may be formed by sequentially depositing the first group III-V semiconductor sub-layer 111 and the second group III-V semiconductor sub-layer 112. The materials of the first group III-V semiconductor sub-layer 111 and the second group III-V semiconductor sub-layer 112 may be AlInGaN series materials, such as gallium nitride (GaN), indium gallium nitride (InGaN) or aluminum gallium nitride (AlGaN). The first group III-V semiconductor sub-layer 111 and the second group III-V semiconductor sub-layer 112 may be doped with the first-conductivity-type dopant. As in the foregoing embodiments, the doping concentration of the first-conductivity-type dopant of the second group III-V semiconductor sub-layer 112 may be greater than that of the first group III-V semiconductor sub-layer 111.

Next, in step S105, the indium-containing layer 116 is formed on the transition layer 115 by epitaxial growth. The composition of the indium-containing layer 116 is, for example, indium gallium nitride Inₓ₁Ga₁₋ₓ₁N, wherein 0<x1≤0.2, or indium aluminum nitride Inₓ₂Al₁₋ₓ₂N, wherein 0<x2≤0.15, and the thickness of the indium-containing layer 116 may be about 7 nm. In some embodiments, the growth temperature of the indium-containing layer 116 may be equal to or slightly less than the growth temperature of the transition layer 115. In some embodiments, the growth conditions, such as temperature and pressure, of the indium-containing layer 116 are the same as those of the transition layer 115. In some embodiments, the growth temperature of indium-containing layer 116 may be between the growth temperatures of transition layer 115 and stress release structure 117. In one embodiment, during a process of adjusting the growth temperature of the transition layer 115 to the growth temperature of the stress release structure 117, the indium-containing layer 116 can be grown at the same time, so as to adjust the epitaxial growth temperature of the semiconductor layers in gradient.

Next, in step S107, the stress release structure 117, the active structure 130 and the second semiconductor structure 120 are sequentially formed on the indium-containing layer 116 by epitaxial growth to form the semiconductor structure 100 in FIG. 1. Details related to the first semiconductor structure 110 can be referred to the description of FIG. 1. In addition, the epitaxial growth temperature of the stress release structure 117 and the active structure 130 may be lower than the epitaxial growth temperature of the indium-containing layer 116. In accordance with some embodiments of the present disclosure, the epitaxial growth temperature of the indium-containing layer 116 may be equal to or less than the epitaxial growth temperature of the transition layer 115 and greater than the epitaxial growth temperature of the active structure 130.

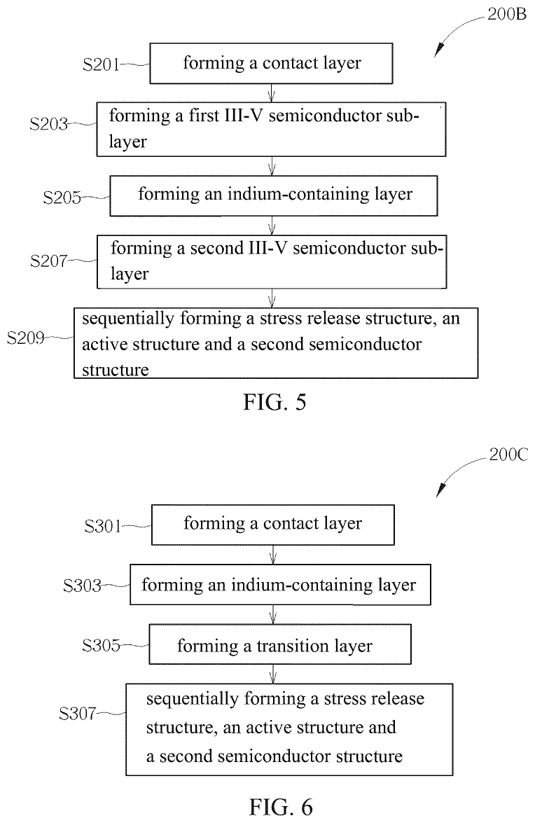

FIG. 5 is a flow chart of a manufacturing method of a semiconductor structure 200B in accordance with another embodiment of the present disclosure. As shown in FIGS. 2 and 5, in step S201, the contact layer 102 of the first semiconductor structure 110 is formed on a growth substrate by epitaxial growth, and the intermediate layer 118 can be selectively formed. The details of the first semiconductor structure 110 already described in step S101 will not be repeated here. Next, in step S203, the first group III-V semiconductor sub-layer 111 of the transition layer 115 is formed on the contact layer 102 or the intermediate layer 118 by epitaxial growth. The material of the first group III-V semiconductor sub-layer 111 may be gallium nitride (GaN) doped with a less concentration of the first-conductivity-type dopant.

Next, in step S205, the indium-containing layer 116 is formed on the first group III-V semiconductor sub-layer 111 by epitaxial growth. The details of the indium-containing layer 116 already described in S105 will not be repeated here. Next, in step S207, the second group III-V semiconductor sub-layer 112 of the transition layer 115 is formed on the indium-containing layer 116 by epitaxial growth. The material of the second group III-V semiconductor sub-layer 112 may be gallium nitride (GaN) doped with a greater concentration of the first-conductivity-type dopant than that of the first group III-V semiconductor sub-layer 111.

Next, in step S209, the stress release structure 117, the active structure 130 and the second semiconductor structure 120 are sequentially formed on the second group III-V semiconductor sub-layer 112 by epitaxial growth method to forming the semiconductor structure 100 in FIG. 2. The details of the stress release structure 117, the active structure 130 and the second semiconductor structure 120 already described in the description of FIG. 1 will not be repeated here. In this embodiment, the epitaxial growth temperature of the indium-containing layer 116 may be substantially equal to the epitaxial growth temperature of the first group III-V semiconductor sub-layer 111 of the transition layer 115 and greater than the epitaxial growth temperature of the active structure 130, but it is not limited thereto.

FIG. 6 is a flow chart of a manufacturing method of a semiconductor structure 200C in accordance with another embodiment of the present disclosure. As shown in FIGS. 3 and 6, in step S201, the contact layer 102 of the first semiconductor structure 110 is formed on a growth substrate by epitaxial growth, and the intermediate layer 118 can be optionally formed. The details of the first semiconductor structure 110 already described in step S101 will not be repeated here.

Next, in step S303, the indium-containing layer 116 is formed on the contact layer 102 or the intermediate layer 118 by epitaxial growth. The details of the indium-containing layer 116 already described in step S105 will not be repeated here. Next, in step S305, the transition layer 115 is formed on the indium-containing layer 116 by epitaxial growth. Details related to the transition layer 115 can be referred to the description in FIG. 1.

Next, in step S307, the stress release structure 117, the active structure 130 and the second semiconductor structure 120 are sequentially formed on the transition layer 115 by epitaxial growth method to forming the semiconductor structure 100 in FIG. 3. The details of the stress release structure 117, the active structure 130 and the second semiconductor structure 120 described in the description of FIG. 1 will not be repeated here. In the embodiment, the epitaxial growth temperature of the indium-containing layer 116 may be substantially equal to or lower than the epitaxial growth temperature of the contact layer 102 or the intermediate layer 118 and greater than the epitaxial growth temperature of the active structure 130, but it is not limited thereto.

In accordance with some embodiments of the present disclosure, in the semiconductor structure 100, the indium-containing layer 116 is disposed between the stress release structure 117 of and the first semiconductor structure 110, and the indium content of the indium-containing layer 116 is greater than the indium content of the stress release structure 117. Indium atoms in the indium-containing layer 116 can be used to combine with the surface defects of the first semiconductor structure 110 formed by a high-temperature epitaxial growth, so that these surface defects are confined by the indium-containing layer 116 and may not extend to the active structure 130. The non-radiative recombination centers (NRCs) in the active structure 130 can be avoided to improve the internal quantum efficiency of the active structure 130, thereby improve the light-emitting efficiency of the semiconductor structure 100. For example, some embodiments of the present disclosure can increase the light-emitting efficiency of the semiconductor structure 100 by about 0.4% to 0.8% compared to a semiconductor structure without the indium-containing layer 116, thereby improving the brightness of the light-emitting device. Moreover, in a photoelectric measurement, the driving voltage of the light-emitting device is maintained and the anti-ESD capability of the light-emitting device is improved.

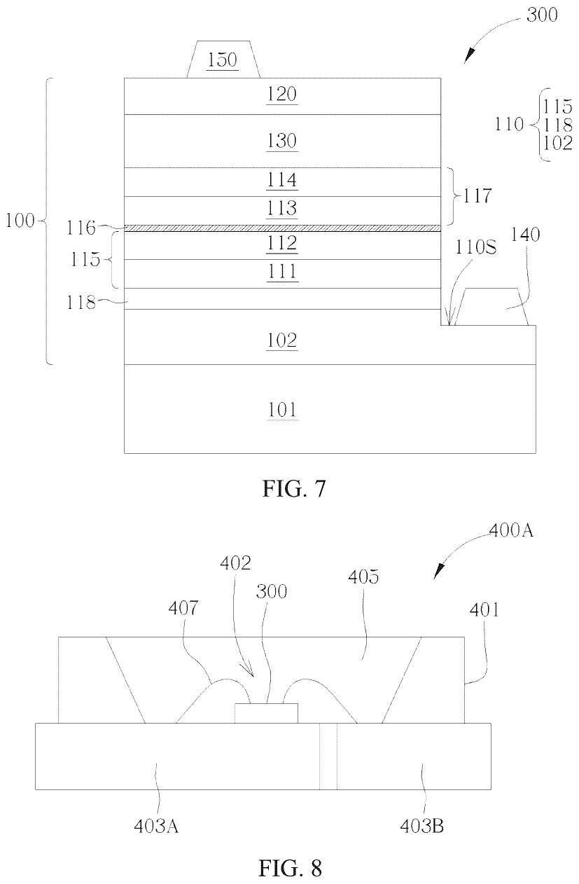

FIG. 7 is a schematic cross-sectional view of a light-emitting device 300 in accordance with an embodiment of the present disclosure. The light-emitting device 300 includes a substrate 101 and a semiconductor structure 100 disposed on the substrate 101. The substrate 101 may be a growth substrate. In one embodiment, the upper surface of the substrate 101 may have a patterned structure (not shown) to emit light from the semiconductor structure 100. The light can be refracted and/or reflected by the patterned structure of the substrate 101, thereby improving the brightness of the light-emitting device 300. The semiconductor structure 100 can be the semiconductor structure 100 of FIGS. 1 to 3. In FIG. 7, the semiconductor structure 100 of FIG. 1 serves as an example, but is not limited thereto. The first semiconductor structure 110 has a surface 110S not covered by the transition layer 115, the indium-containing layer 116, the stress release structure 117, the active structure 130 and the second semiconductor structure 120. The first electrode 140 is disposed on the surface 110S of the first semiconductor structure 110 to be electrically connected to the first semiconductor structure 110. The second electrode 150 is disposed on the second semiconductor structure 120 to be electrically connected to the second semiconductor structure 120. In one embodiment, a transparent conductive layer (not shown) may be disposed between the second electrode 150 and the second semiconductor structure 120. For a current blocking purpose, a patterned insulating layer may be disposed between the second electrode 150 and the second semiconductor structure 120, and/or another patterned insulating layer may be disposed between the first electrode 140 and the first semiconductor structure 110.

The first electrode 140 and the second electrode 150 are for electrically connecting to an external power source or other electronic components and for conducting a current therebetween. Materials of the first electrode 140 and the second electrode 150 include metal materials. Metal materials include chromium (Cr), gold (Au), aluminum (Al), copper (Cu), silver (Ag), tin (Sn), nickel (Ni), rhodium (Rh), platinum (Pt), germanium gold nickel (GeAuNi), titanium (Ti), beryllium gold (BeAu), germanium gold (GeAu) or zinc gold (ZnAu). In some embodiments, each of the first electrode structure 201 and the second electrode structure 208 is a single layer, or a structure including multiple layers such as Ti/Au layer, Ti/Al layer, Ti/Pt/Au layer, Cr/Au layer, Cr/Pt/Au layer, Ni/Au layer, Ni/Pt/Au layer, Ti/Al/Ti/Au layer, Cr/Ti/Al/Au layer, Cr/Al/Ti/Au layer, Cr/Al/Ti/Pt layer or Cr/Al/Cr/Ni/Au layer, or a combination thereof. The material of the transparent conductive layer includes transparent conductive oxide or light-transmissive thin metal. The transparent conductive oxides are, for example, indium tin oxide (ITO), indium oxide (InO), tin oxide (SnO), cadmium tin oxide (CTO), antimony tin oxide (ATO), aluminum zinc oxide (AZO), zinc tin oxide (Zn₂SnO₄, ZTO), gallium doped zinc oxide (GZO), tungsten doped indium oxide (IWO), zinc oxide (ZnO) or indium zinc oxide (IZO). Among them, thin metals that can transmit light are chromium (Cr), gold (Au), aluminum (Al), copper (Cu), silver (Ag), tin (Sn), nickel (Ni), rhodium (Rh), platinum (Pt) or titanium (Ti).

FIG. 8 is a schematic cross-sectional view of a light-emitting package 400A in accordance with an embodiment of the present disclosure. As shown in FIG. 8, the light-emitting package 400A includes a body 401 having a chamber 402, a first terminal 403A and second terminal 403B disposed in the body 401, a light-emitting device 300, wires 407 and a packaging material 405. The chamber 402 may include an opening structure recessed from the top surface of the body 401. In one embodiment, the sidewall of the chamber 402 may include a reflective structure. The first terminal 403A is arranged in a first region of a bottom area of the chamber 402, the second terminal 403B is arranged in a second area of the bottom area of the chamber 402. In the chamber, the first terminal 403A and the second terminal 403B are spaced apart from each other. The light-emitting device 300 is disposed on at least one of the first and second terminals 403A and 403B. For example, the light-emitting device 300 can be disposed on the first terminal 403A, and the first electrode (such as the first electrode 140 in FIG. 7) and the second electrode (such as the second electrode 150 in FIG. 7) of the light-emitting devices 300 are electrically connected to the first and second terminals 403A and 403B by wires 407, respectively. The packaging material 405 is disposed in the chamber 402 of the body 401 and covers the light-emitting device 300. The packaging material 405 includes, for example, silicon or epoxy resin, and the structure thereof can be single-layer or multi-layer. In one embodiment, the packaging material 405 may further include a wavelength conversion material, such as phosphor and/or a scattering material, for converting the wavelength of the light generated by the light-emitting device 300. The light-emitting device 300 can be the light-emitting device 300 shown in FIG. 7. The light-emitting package 400A may be applied to a backlight unit, a lighting unit, a display device, an indicator, a lamp, a street lamp, a lighting device for a vehicle, a display device for a vehicle, or a smart watch, but is not limited thereto.

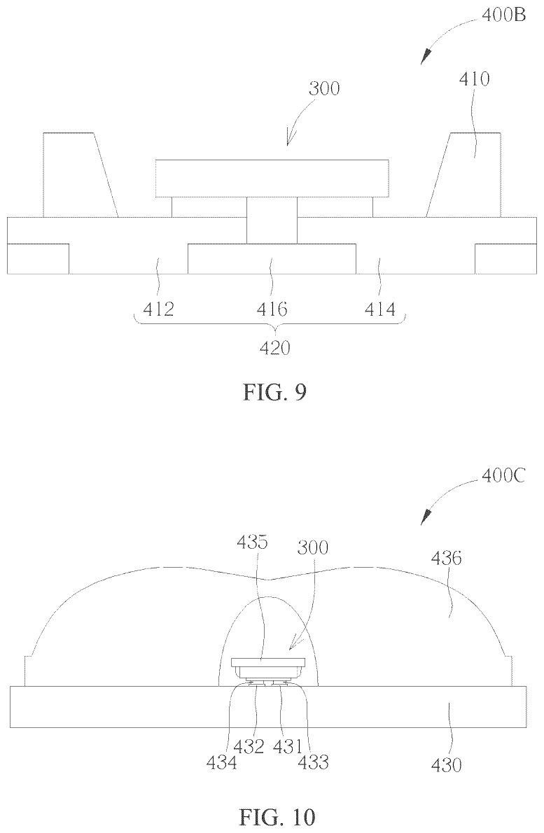

FIG. 9 is a schematic cross-sectional view of a light-emitting package 400B in accordance with another embodiment of the present disclosure. The light-emitting device 300 is mounted on a first pad 412 and a second pad 414 of a packaging substrate 420 in a flip-chip form. The first pad 412 and the second pad 414 are electrically insulated by an insulating portion 416 containing an insulating material. In a flip-chip mounting, a side of the substrate 101 facing the pads is placed upward to be a main light extraction surface. In order to increase the light extraction efficiency of the light-emitting device, a reflective structure 410 can be provided around the light-emitting device 300. The light-emitting device 300 can be the light-emitting device 300 shown in FIG. 7.

FIG. 10 is a schematic cross-sectional view of a light-emitting package 400C in accordance with another embodiment of the present disclosure. The light-emitting package 400C includes a support substrate 430, a light emitting device 300, a wavelength converter 435 and a lens 436. A first bump 433 and a second bump 434 on the light-emitting device 300 are bonded to a first bonding pad 431 and a second bonding pad 432 on the support substrate 430 in a flip-chip form. The support substrate 430 may be a printed circuit board. In addition, the lens 436 is disposed above the light-emitting device 300. The lens 436 can be a diffusion lens for light-diffusion, but is not limited thereto. Depending on different shapes of the lens 436 combined with the light-emitting device 300, various light patterns can be realized. The light-emitting device 300 may be the light-emitting device 300 shown in FIG. 7.

FIG. 11 is a schematic cross-sectional view of a light-emitting apparatus 500A in accordance with an embodiment of the present disclosure. Referring to FIG. 11, the light-emitting apparatus 500A includes a display panel 510 and a backlight unit. The backlight unit includes light-emitting devices 300, a bottom cover 501, a reflective sheet 502, a diffusion sheet 503 and an optical sheet 504. The bottom cover 501 can be opened upward to accommodate the light-emitting device 300, the reflective sheet 502, the diffusion sheet 503 and the optical sheet 504. The light-emitting device 300 can be the light-emitting device 300 in FIG. 7 or a light-emitting package in the forgoing embodiments. In an embodiment, disposing an optical element 505 on each light-emitting device 300 can improve the uniformity of the light emitted from the plurality of light-emitting devices 300. The diffusion sheet 503 and the optical sheet 504 are located on the light-emitting device 300, and the light emitted from the light-emitting device 300 can be supplied to the display panel 510 in the form of a surface light source through the diffusion sheet 503 and the optical sheet 504.

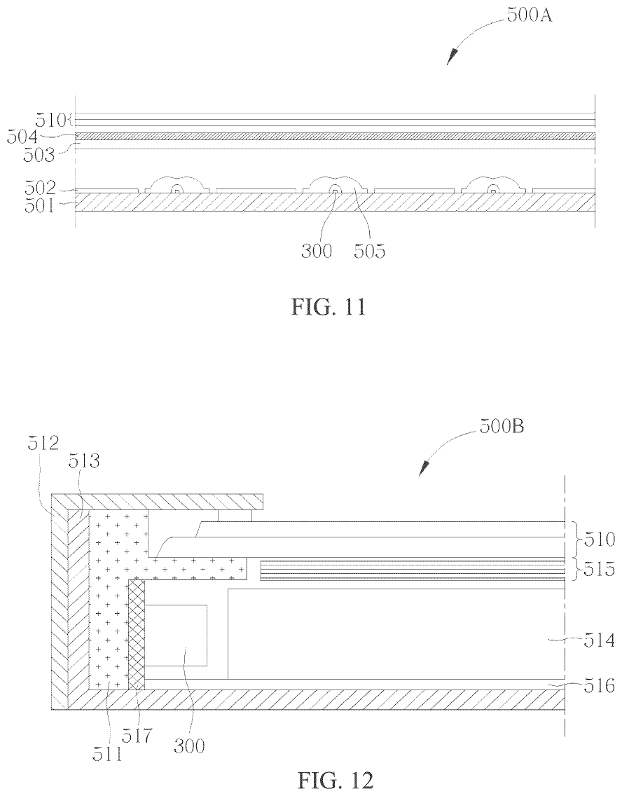

FIG. 12 is a schematic cross-sectional view of a light-emitting apparatus 500B in accordance with an embodiment of the present disclosure. Referring to FIG. 12, the light-emitting apparatus 500B includes a display panel 510 and a backlight unit disposed under the display panel 510. Furthermore, the light-emitting apparatus 500B includes: a frame 511 supporting the display panel 510 and housing the backlight unit, and covers 512 and 513 of the display panel 510. The display panel 510 can be fixed by the covers 512 and 513 respectively located above and below it, and the cover 513 located below can be combined with the backlight unit. The backlight unit includes a light guide plate 514, an optical sheet 515, a reflective sheet 516, a carrier plate 517 and a plurality of light-emitting devices 300. The optical sheet 515 is located on the light guide plate 514 to diffuse the light, the reflective sheet 516 is located under the light guide plate 514 to reflect the light traveling under the light guide plate 514 to the direction of the display panel 510, and the light-emitting devices 300 are arranged at intervals on the carrier plate 517. In an embodiment, the carrier plate 517 may be a printed circuit board. The light-emitting devices 300 can be the light-emitting devices or the light-emitting packages in the foregoing embodiments.

It is noted that each of the embodiments listed in the present application is merely used to describe the present application, not limiting the scope of the present application. It will be apparent to any one that obvious modifications or variations can be made to the devices in accordance with the present disclosure without departing from the spirit and scope of the present application. Identical or similar components in different embodiments or the components having identical reference numerals in different embodiments have identical physical properties or chemical properties. In addition, under suitable circumstances, the above-mentioned embodiments in the present application may be combined or replaced with each other, not limiting to the specific embodiments described above. In one embodiment, the connecting relationship of the specific component and other component described in detail may also be applied into other embodiments, falling within the scope of the following claims and their equivalents of the present application.

What is claimed is:

1. A semiconductor structure, comprising:
a first semiconductor structure comprising a first conductivity type;
a second semiconductor structure comprising a second conductivity type;
an active structure between the first semiconductor structure and the second semiconductor structure;
a stress release structure disposed between the first semiconductor structure and the active structure; and
an indium-containing layer disposed between the stress release structure and the first semiconductor structure;
wherein an indium content of the indium-containing layer is greater than that of the stress release structure.

2. The semiconductor structure of claim 1, wherein a material of the indium-containing layer comprises Inₓ₁Ga₁₋ₓ₁N, wherein 0<x1≤0.2.

3. The semiconductor structure of claim 1, wherein a material of the indium-containing layer comprises Inₓ₂Al₁₋ₓ₂N, wherein 0<x2≤0.15.

4. The semiconductor structure of claim 1, wherein a thickness of the indium-containing layer is between 0.25 nm and 20 nm.

5. The semiconductor structure of claim 1, wherein the first semiconductor structure comprises a contact layer and a transition layer disposed between the contact layer and the stress release structure.

6. The semiconductor structure of claim 5, wherein the indium-containing layer is disposed between the stress release structure and the transition layer.

7. The semiconductor structure of claim 5, wherein the indium-containing layer is disposed between the transition layer and the contact layer.

8. The semiconductor structure of claim 5, wherein the first semiconductor structure further comprises an intermediate layer disposed between the contact layer and the transition layer.

9. The semiconductor structure of claim 8, wherein the intermediate layer and the contact layer comprise a first-conductivity-type dopant, and a concentration of the first-conductivity-type dopant in the contact layer is greater than that in the intermediate layer.

10. The semiconductor structure of claim 5, wherein the transition layer comprises a first group III-V semiconductor sub-layer disposed on the contact layer and a second group III-V semiconductor sub-layer disposed on the first group III-V semiconductor sub-layer.

11. The semiconductor structure of claim 10, wherein the first group III-V semiconductor sub-layer and the second group III-V semiconductor sub-layer respectively comprises a first-conductivity-type dopant.

12. The semiconductor structure of claim 11, wherein a concentration of the first-conductivity-type dopant in the second group III-V semiconductor sub-layer is greater than that in the first group III-V semiconductor sub-layer.

13. The semiconductor structure of claim 12, wherein the indium-containing layer is disposed between the first group III-V semiconductor sub-layer and the second group III-V semiconductor sub-layer.

14. The semiconductor structure of claim 1, wherein the stress release structure comprises a first stress release layer on the indium-containing layer.

15. The semiconductor structure of claim 14, wherein the stress release structure further comprises a second stress release layer between the first stress release layer and the indium-containing layer.

16. The semiconductor structure of claim 15, wherein an indium content of the second stress release layer is greater than that of the first stress release layer.

17. The semiconductor structure of claim 15, wherein the first stress release layer and/or the second stress release layer comprise a plurality of sub-layers.

18. The semiconductor structure of claim 17, wherein part of the plurality of sublayers of the first stress release layer and/or part of the plurality of sublayers of the second stress release layer comprise indium.

19. The semiconductor structure of claim 15, wherein the second stress release layer comprises a plurality of sub-layers, and the second stress release layer comprises the indium-containing layer.

20. The semiconductor structure of claim 1, wherein the indium content of the indium-containing layer is 2 to 3 times that of the stress release structure.
